(19) United States
(12) Patent Application Publication
(10) Pub. No.: US 2007/0018217 A1
(43) Pub. Date: Jan. 25, 2007

(54) Semiconductor device and manufacturing method of the same

(75) Inventor: Hiroe Kawamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/370,957

(22) Filed: Mar. 9, 2006

(30) Foreign Application Priority Data
Jul. 6, 2005 (JP) 2005-198010

(51) Int. Cl. H01L 29/94

(52) U.S. Cl. 257/296

(57) ABSTRACT

According to the present invention, a semiconductor device manufacturing method includes the steps of: forming a capacitor formation groove in a silicon (semiconductor) substrate; and forming a second insulating film by thermally oxidizing at least the upper surface of the silicon substrate and the bottom and the side surfaces of the capacitor formation groove, wherein either the step of implanting fluorine ions in the upper surface of the silicon substrate and the bottom of the capacitor formation groove is performed before the step of forming the second insulating film, or the step of forming the second insulating film is performed by thermally oxidizing the upper surface of the silicon substrate and the bottom and the side surfaces of the capacitor formation groove in the vapor atmosphere in the reduced pressure state.

### CROSS-REFERENCE TO RELATED APPLICATIONS

This application is based on and claims priority of Japanese Patent Application No. 2005-198010 filed on Jul. 6, 2005, the entire contents of which are incorporated herein by reference.

### BACKGROUND OF THE INVENTION

1. Field of the Invention

The present invention relates to a semiconductor device and a method of manufacturing a semiconductor device.

2. Description of the Related Art

For a semiconductor device that employs a silicon substrate, for various purposes, not only a MOS transistor but also a capacitor is formed on the silicon substrate. There are several methods for forming a capacitor. According to a method in which a groove is formed in a silicon substrate and then a capacitor dielectric film and an upper electrode are laminated in the groove, there are advantages that the area of the capacitor electrodes are enlarged due to the bottom and the side surfaces of the groove, and thus a large capacitance can be obtained.

In this case, a thermal oxide film obtained by thermally oxidizing the inner surfaces of the groove is used as the capacitor dielectric film.

However, as disclosed in the following Patent Literature 1, the thermal oxide film grows thicker on the side surface of the groove than on the bottom surface by 1.3 to 2.0 times. According to the Patent Literature 1, such thickness difference is thought to be generated by different oxidizing rate between side and bottom surfaces, which is caused by difference in surface densities of the silicon atoms due to the different plane directions of silicon between side and bottom surfaces.

However, it is not preferable for the thermal oxide film, which serves as a capacitor dielectric film, to become thick on the side surface of the groove, since the distance between the capacitor electrodes would be increased and the capacitance reduced. Further, the effect obtained by using the groove to increase the capacitance would be reduced.

In addition to the Patent Literature 1, techniques relating to the present invention are also disclosed in the following Patent Literatures 2 to 7.

According to the Patent Literature 2, when a trench capacitor is formed using a groove in a silicon substrate, ion implantation is performed only at the corners of the groove, and thereafter, a thermal oxide film is formed on the silicon substrate. Therefore, the occurrence of a “horn phenomenon”, where the corners of the silicon substrate are projected and the thermal oxide film thereon is thinned, is prevented, and thus increased leakage current at the corners is suppressed.

According to the Patent Literature 3, in order to prevent the above described “horn phenomenon”, a silicon substrate is exposed to an oxide atmosphere containing a fluorine compound, and thereafter, a thermal oxide film is formed on the silicon substrate.

According to the Patent Literature 4, at the bottom of the groove for a trench capacitor, a thick thermal oxide film is formed by using speed increasing oxidization using arsenic, while a thin thermal oxide film is formed on the side surfaces of the groove. Then, while employing these thermal oxide films as through films, impurities are again ion-implanted in the groove. As a result, at the bottom of the groove, the amount of implanted impurities is reduced by blocking much of the impurities using the thick oxide film, and at the side surfaces of the grooves, a large amount of impurities is introduced through the thin oxide film. In this manner, an impurity region having a uniform depth is formed in the side surfaces and in the bottom surface of the groove.

According to the Patent Literature 5, when a capacitor is formed on the device isolation region of a silicon substrate, a capacitor lower electrode, which is formed of silicon into which impurities have been introduced, is thermally oxidized by exposing it to a water vapor atmosphere of the reduced pressure. In this manner, speed increasing oxidization on the surface of the capacitor lower electrode is suppressed, and a capacitor insulating film, made of the thin thermal oxide film, is obtained.

According to the Patent Literature 6, a groove used for a trench capacitor and a groove used for device isolation are formed in a silicon substrate at the same step.

According to the Patent Literature 7, the surface of a silicon substrate is exposed to Kr (krypton) plasma to remove hydrogen from the surface terminal ends, and then a thermal oxide film is formed by oxidizing the surface of the silicon substrate in the atmosphere consisting of a gas mixture of Kr and O₂.

[Patent Literature 1] Japanese Patent Laid-Open Publication No. 2003-69010

[Patent Literature 2] Japanese Patent Laid-Open Publication No. Sho 63-133664

[Patent Literature 3] Japanese Patent Laid-Open Publication No. Sho 62-169356

[Patent Literature 4] Japanese Patent Examined Publication No. Hei 7-40586

[Patent Literature 5] Japanese Patent Laid-Open Publication No. 2003-229493

[Patent Literature 6] Japanese Patent Laid-Open Publication No. 2003-309182

[Patent Literature 7] Japanese Patent Laid-Open Publication No. 2002-261091

### SUMMARY OF THE INVENTION

According to one aspect of the present invention, there is provided a semiconductor device comprising: a semiconductor substrate in which a groove is formed; and an insulating film obtained by thermally oxidizing an upper surface of the semiconductor substrate and a side surface and a bottom surface of the groove, wherein the thickness of the insulating film formed on the side surface of the groove is less than 1.3 times the respective thicknesses of the insulating film formed on the upper surface of the semiconductor substrate and the bottom surface of the groove.

According to another aspect of the present invention, there is provided

A semiconductor device manufacturing method comprising the steps of: forming a groove in a semiconductor device; and forming an insulating film by at least thermally oxidizing an upper surface of the semiconductor substrate and a bottom surface and side surfaces of the groove, wherein a step of ion-implanting fluorine ions into the upper surface of the semiconductor substrate and the bottom surface of the groove is performed before the step of forming the insulating film, or the step of forming the insulating film is performed by thermally oxidizing the upper surface of the semiconductor substrate and the bottom surface and the side surface of the groove in a water vapor atmosphere of a reduced pressure state.

The operation of the present invention will now be explained.

According to the present invention, after fluorine ions are implanted into the upper surface of the semiconductor substrate and the bottom of the groove, the upper surface and the groove are thermally oxidized to obtain an insulating film. With this method, since the oxidization speed at the upper surface of the semiconductor substrate and at the bottom of the groove is increased because of the use of fluorine, the difference in the thickness of the insulating film is reduced between the upper surface of the semiconductor substrate and the bottom of the groove, and the side surfaces where growth of the thermal oxide film is rapid. Thus, the thickness of the insulating film on the side surfaces can be less than 1.3 times the thickness on the bottom and the upper surface.

Instead of the ion implantation of fluorine, the upper surface of the semiconductor substrate and the bottom and the side surfaces of the groove may be thermally oxidized in a water vapor atmosphere of a reduced pressure state. Using this method, an insulating film can be obtained for which there are only small differences in the thickness as in the above.

When, for example, the above described insulating film is employed as a capacitor dielectric film, a thin insulating film can be formed on the entire upper surface of the semiconductor substrate and on the bottom and the side surfaces of the groove, and thus the capacitance of the capacitor can be increased.

When fluorine ion implantation is adopted, by ion-implanting fluorine into the bottom of the groove from the direction perpendicular to the in-plane direction of the semiconductor substrate, the amount of fluorine ions implanted into the upper surface of the semiconductor substrate and in the bottom of the groove is increased as compared with the amount in the side surfaces of the groove. As a result, the effects of speed increasing oxidization can be provided only for the bottom of the groove, and hence the insulating film on the side surfaces of the groove can be prevented from becoming unnecessarily thick due to the action of fluorine. As such, differences in the thickness of the insulating film can be efficiently reduced.

On the other hand, when the above described insulating film is formed by thermal oxidization in a water vapor atmosphere in a reduced pressure state, it is preferable that a chamber be supplied with hydrogen and oxygen, and that in this chamber, the hydrogen and oxygen be allowed to react with each other on a heated semiconductor substrate to perform the above described oxidization.

Further, in this case, before thermal oxidization, it is preferable that a reducing gas be introduced into the above chamber and that the upper surface of the semiconductor substrate and the groove be exposed to the reducing gas, and that thereafter, without removing the semiconductor substrate from the chamber, the semiconductor substrate and the groove be successively exposed to the above described water vapor atmosphere to form an insulating film on the semiconductor substrate and in the groove.

Using this method, since a natural oxide film, which is formed on the upper surface of the semiconductor substrate and on the inner surfaces of the groove, is removed by the reducing gas, clear surface of the semiconductor substrate appear on the upper surface and on the inner surfaces of the groove, and the above described insulating film, which is a high quality thermal oxide film, can be formed on the clear surfaces. As a result, the reliability of a capacitor that employs the insulating film as a capacitor dielectric film and of an MOS transistor that employs the insulating film as a gate insulating film is increased.

In addition, an insulating film in the first region of the semiconductor substrate may be used as a gate insulating film, and the insulating film above the groove may also be used as a capacitor dielectric film.

As previously described, in this invention, there are only small differences in the thicknesses of the insulating film formed on the side surfaces and at the bottom of the groove. Therefore, by forming the thin insulating on the upper surface of the semiconductor substrate, the thin insulating film is also automatically formed on the side surfaces of the groove. Therefore, without thinning the insulating film on the first region of the semiconductor substrate unnecessarily, the insulating film to be used as the capacitor dielectric film can be formed in the inner surface of the groove with thin thickness. Therefore, capacitance of the capacitor can be increased while maintaining the breakdown voltage of the gate insulating film of the first region, which in turn makes it possible to simultaneously attain the increased reliability of the MOS transistor and the increased capacitance of the capacitor.

Moreover, unlike group III elements or group V elements, implanted fluorine ions rarely become a carrier source, and therefore, do not adversely affect the MOS transistor electrically.

### BRIEF DESCRIPTION OF THE DRAWINGS

FIGS. 1A to 1O are cross-sectional views of the processing for the manufacture of a semiconductor device according to a first embodiment of the present invention;

FIGS. 2A to 2C are cross-sectional views for explaining an experiment conducted by the present inventor to examine the effects of fluorine ion implantation for the first embodiment of the invention;

FIG. 3 is a graph obtained by calculating a ratio of a thickness of a thermal oxide film when fluorine ions are implanted and when fluorine ions are not implanted;

FIG. 4 is a graph obtained by calculating a ratio of a thickness of a thermal oxide film on the side surfaces and at the bottom of the groove in a silicon substrate in which fluorine ions are implanted;

FIGS. 5A and 5B are plan views for explaining the plan direction for a semiconductor substrate that can be adopted according to first to third embodiments of the present invention;

FIG. 6 is a diagram showing the structure of a process chamber used for the second embodiment of the present invention;

FIG. 7 is a graph obtained by calculating a ratio of the thicknesses of thermal oxide films that are formed on two silicon substrates, the plane directions for the surfaces of which are (100) and (110), according to the second embodiment of the invention; and

FIGS. 8A to 8E are cross-sectional views of the processing for the manufacture of a semiconductor device according to the third embodiment of the present invention.

### DESCRIPTION OF THE PREFERRED EMBODIMENTS

The preferred embodiments of the present invention will now be described in detail while referring to the accompanying drawings.

### (1) First Embodiment

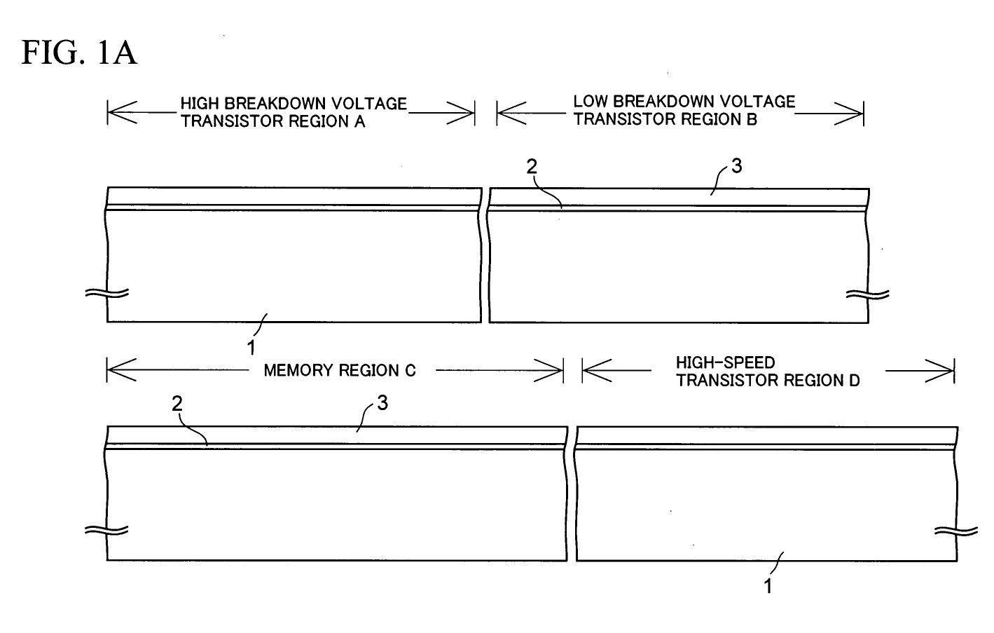

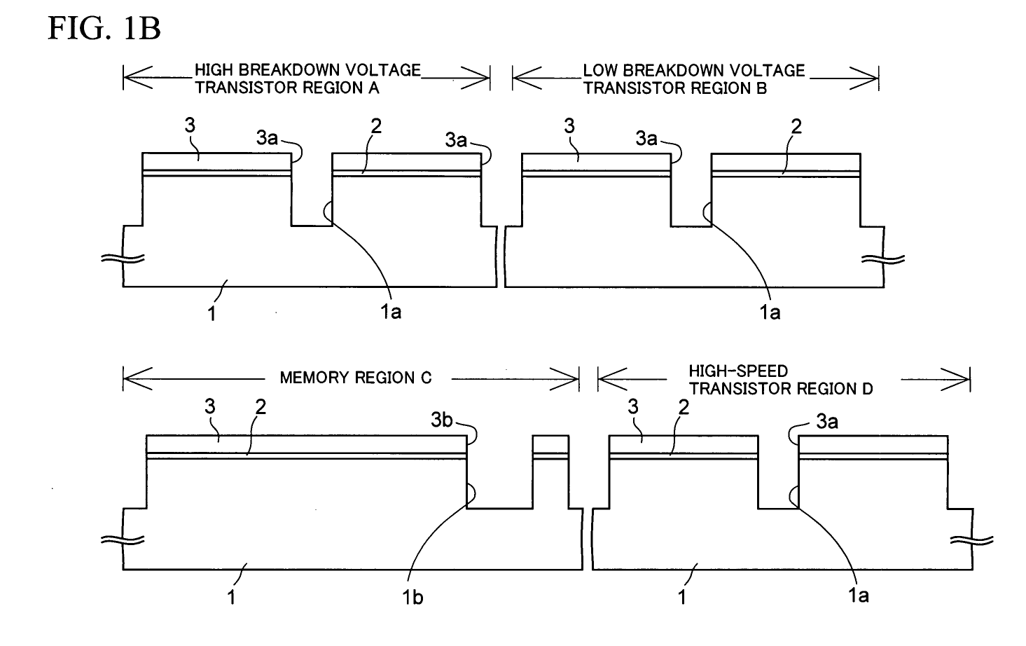

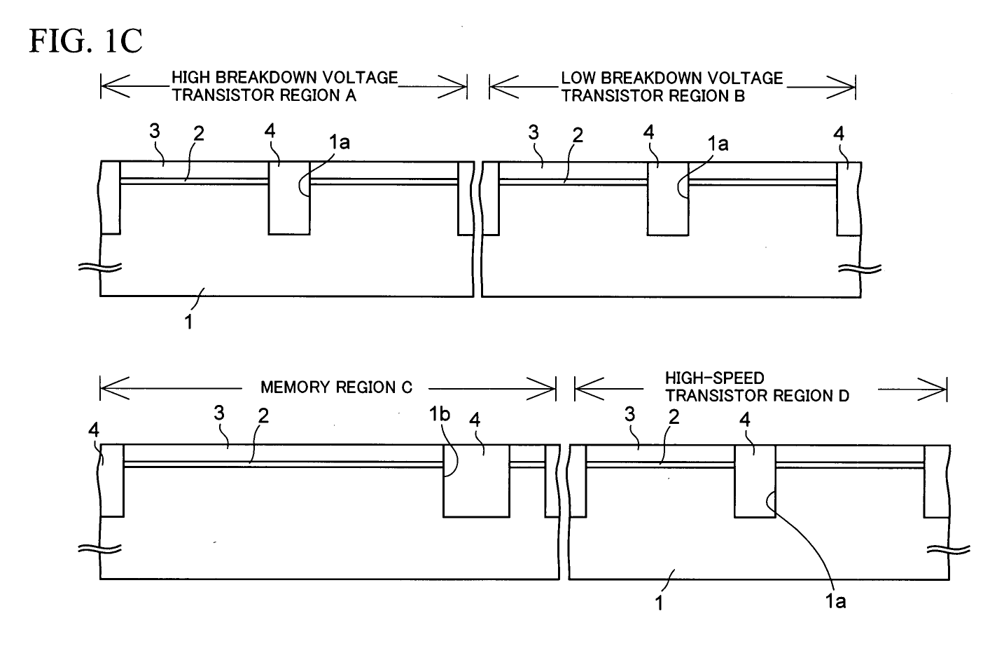

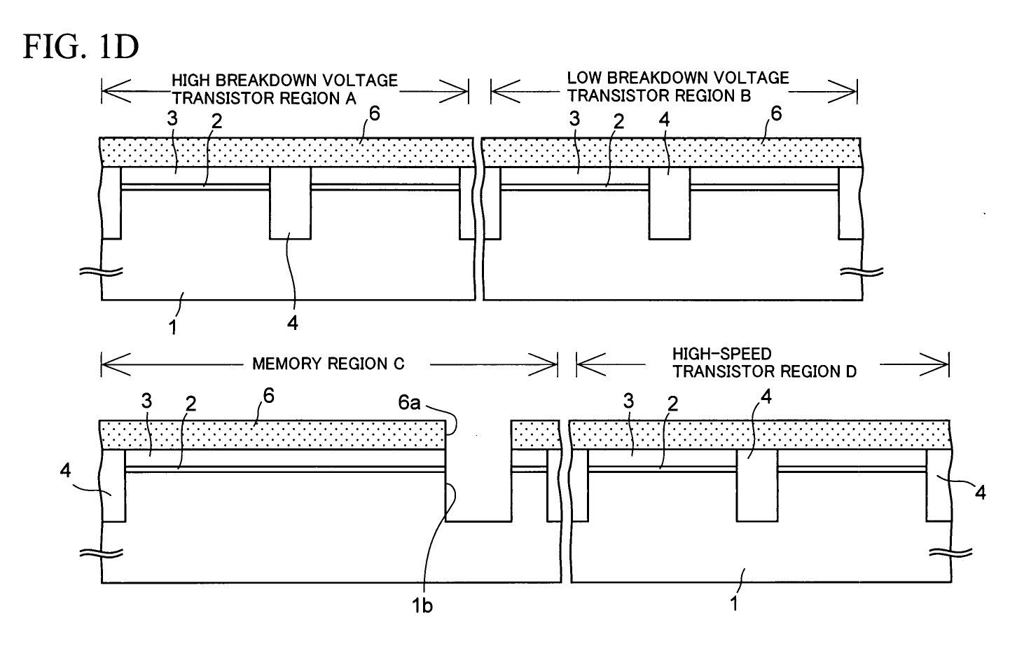

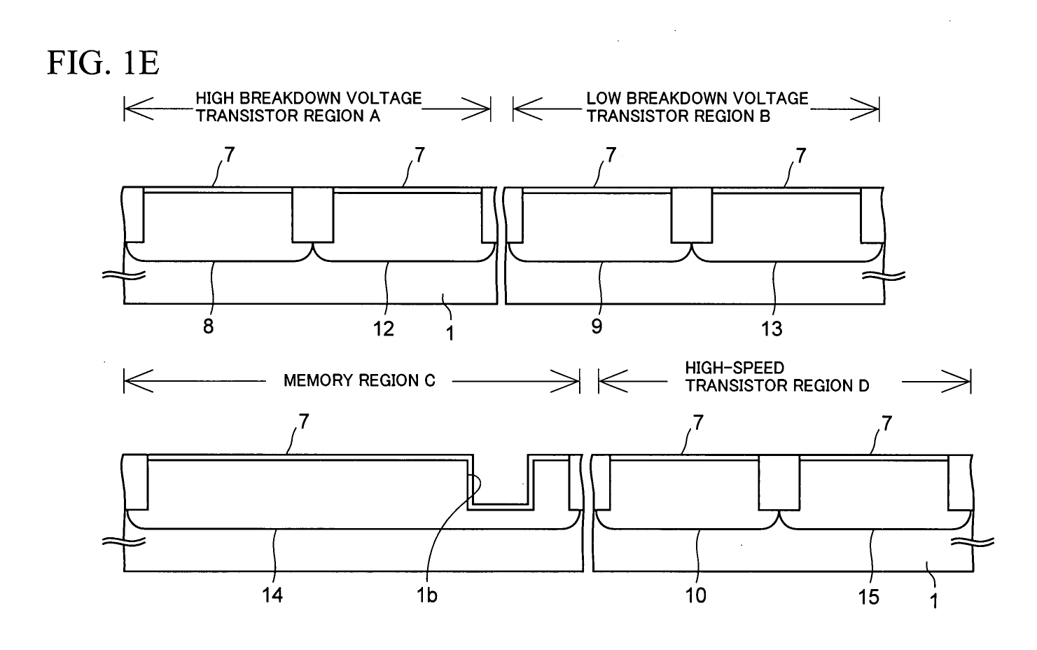

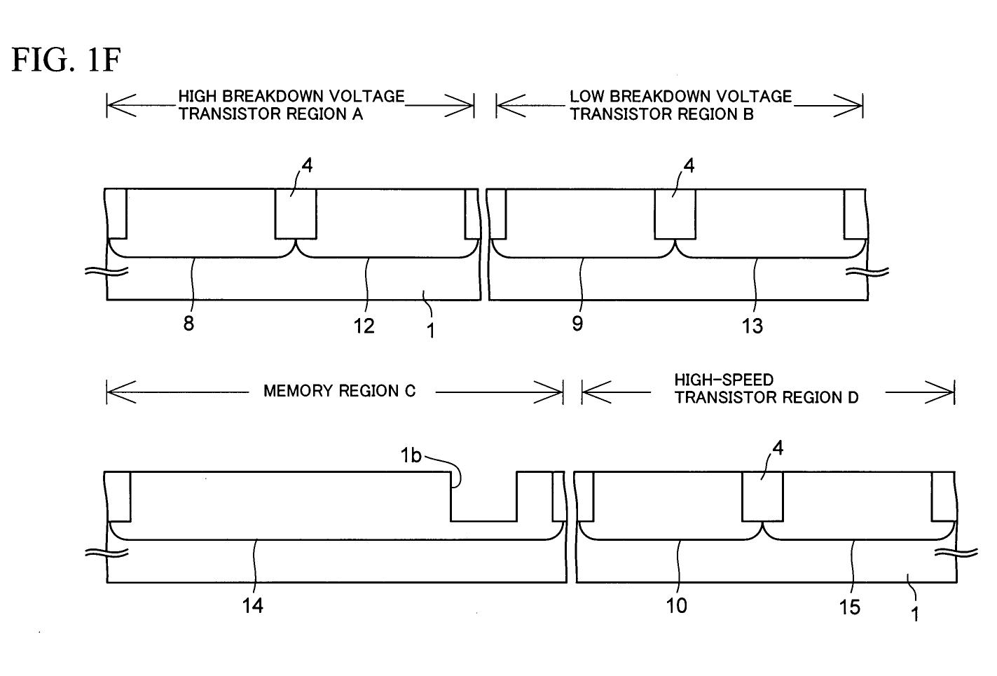

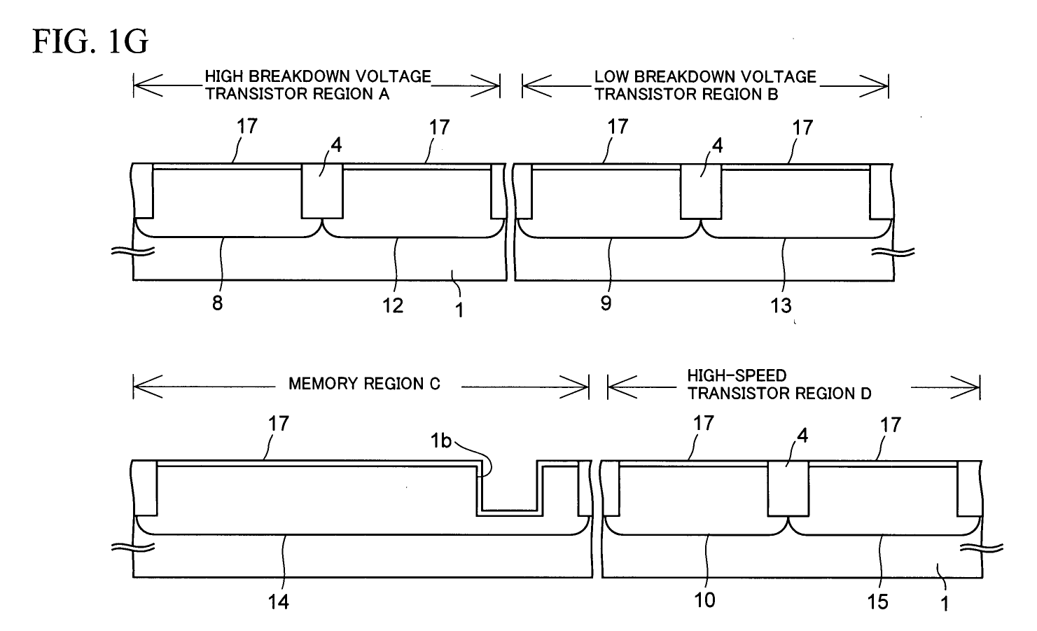

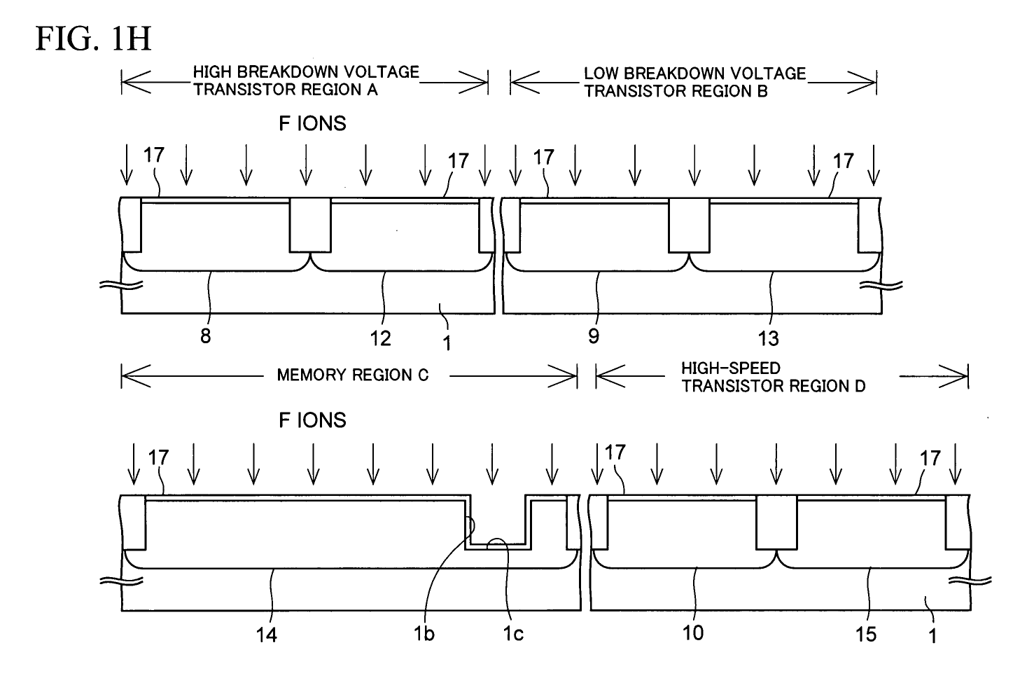

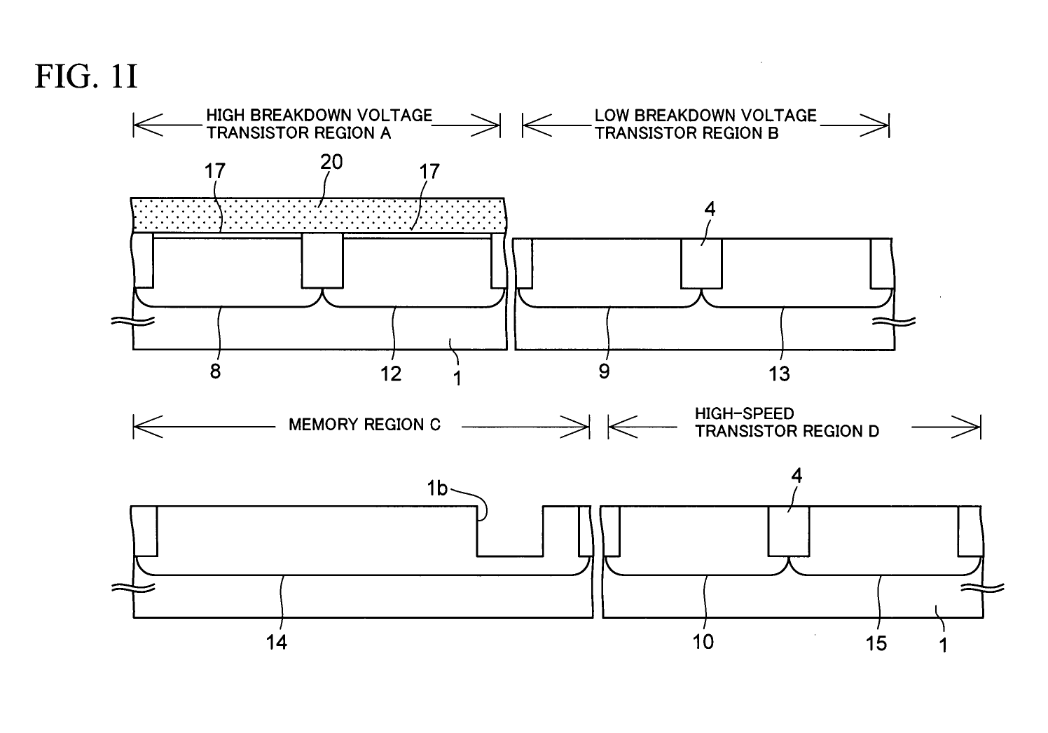

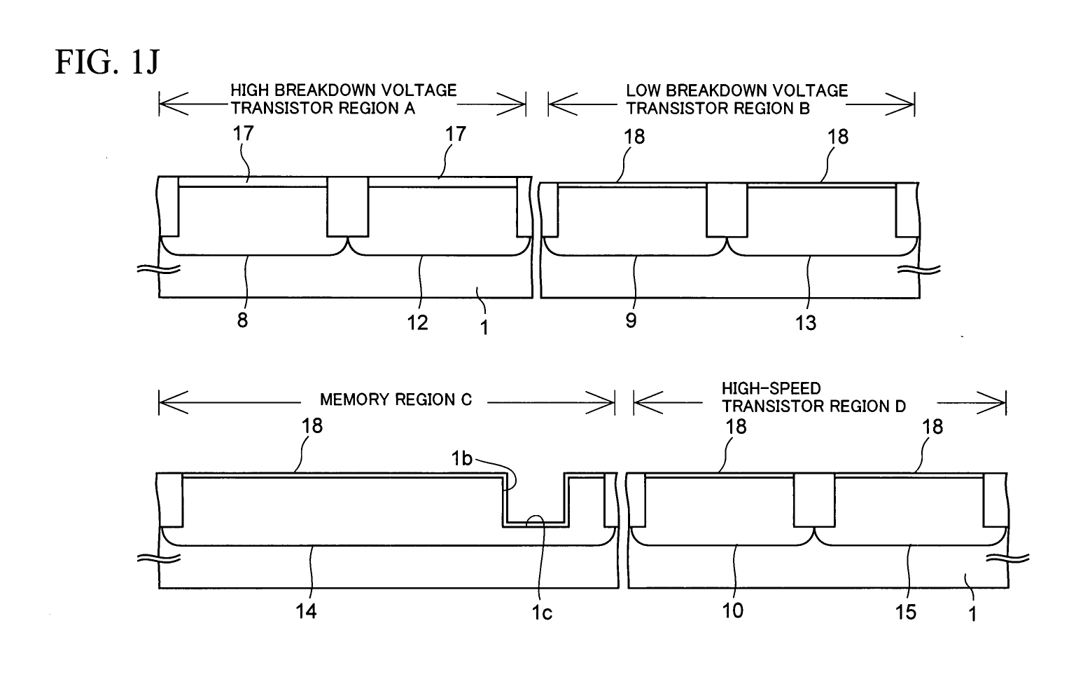

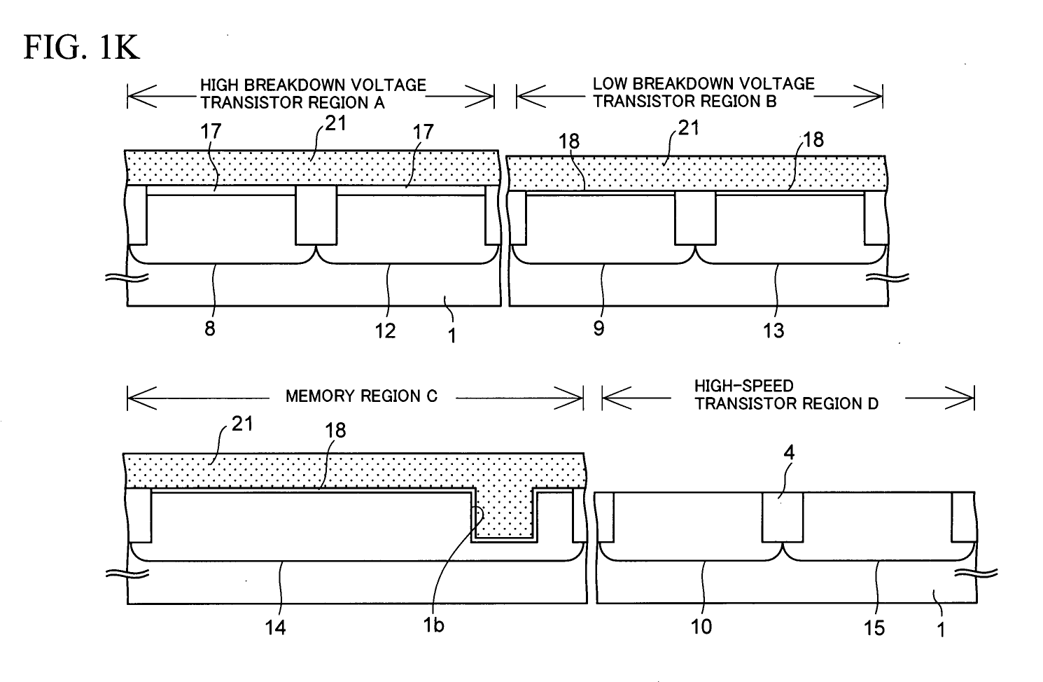

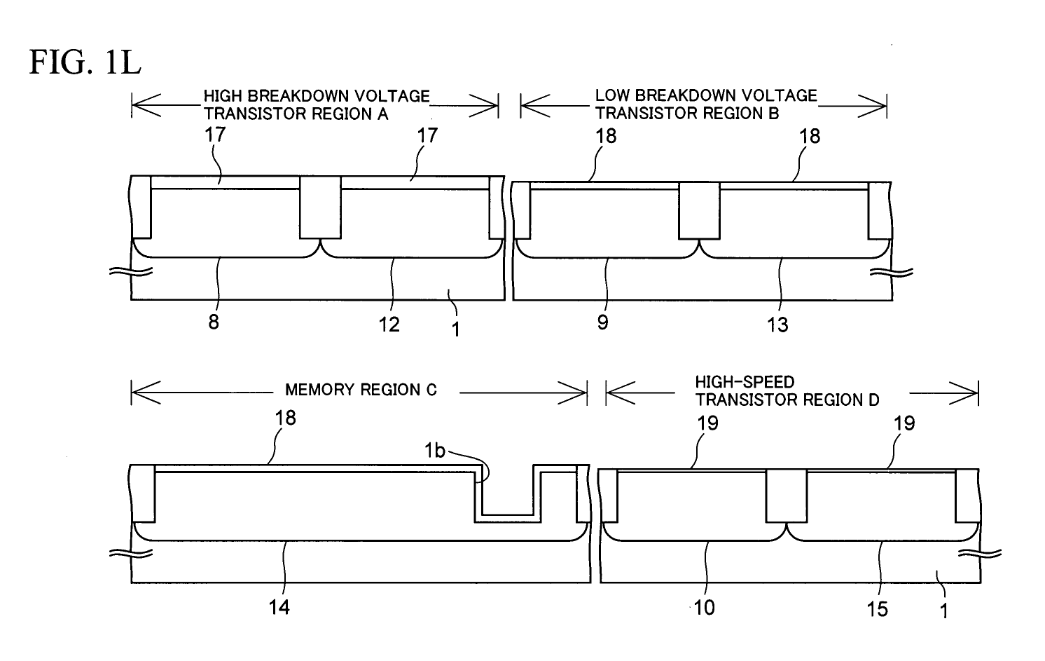

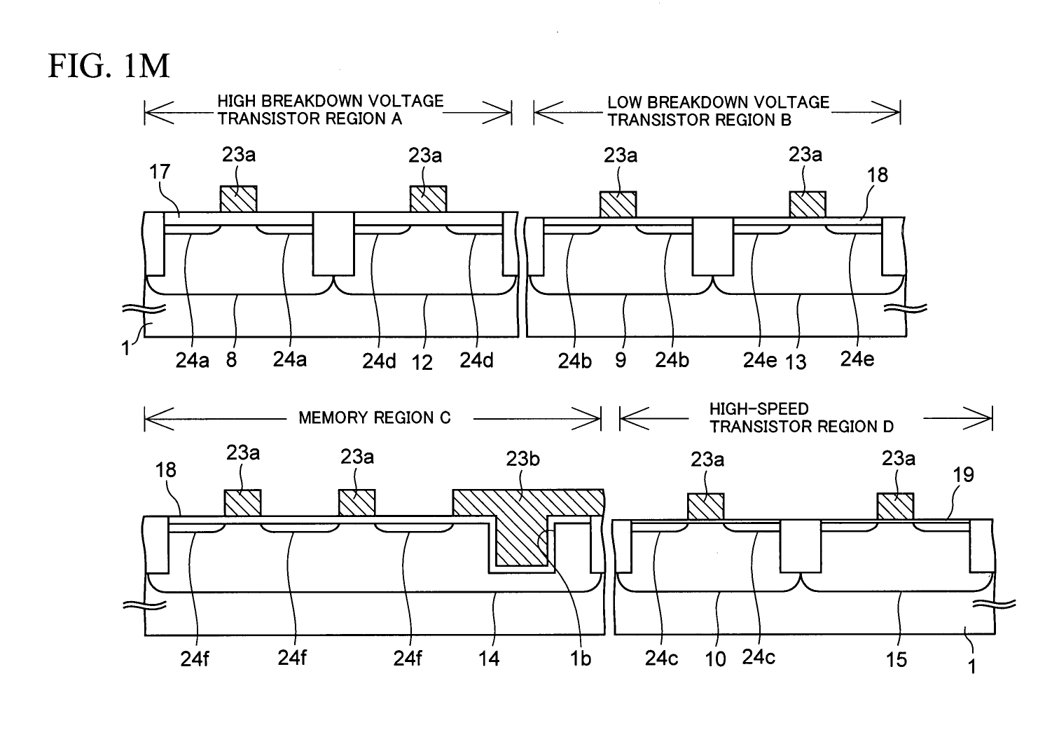

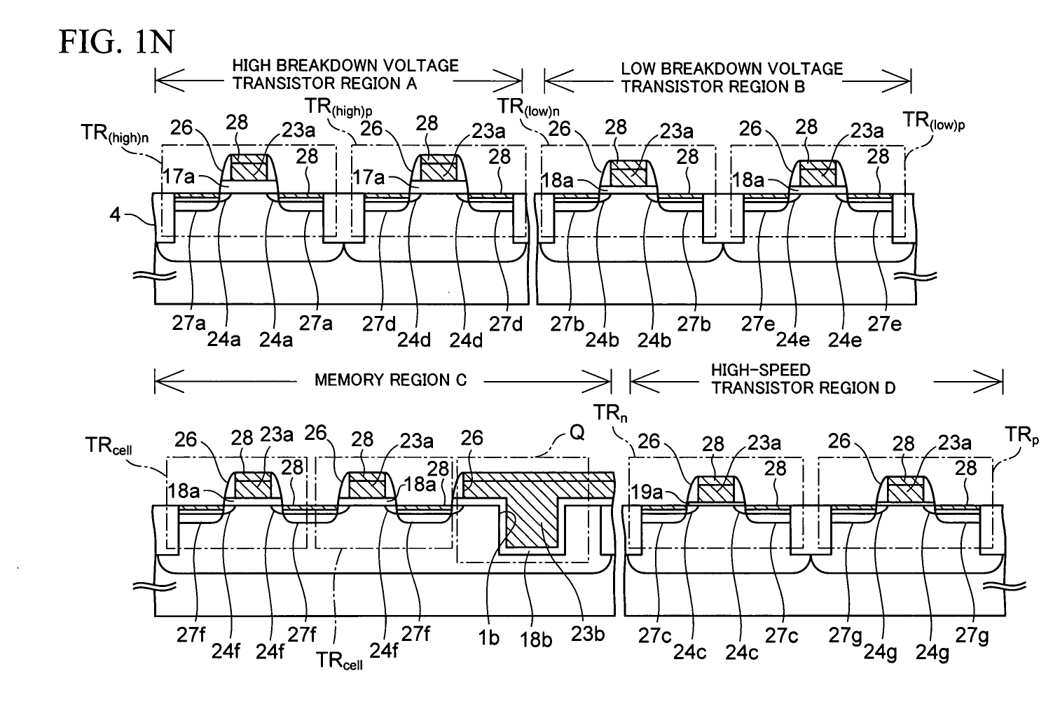

FIGS. 1A to 10 are cross-sectional views of the processing for the manufacture of a semiconductor device according to a first embodiment of the present invention.

Firstly, a process performed until the structure in cross section shown in FIG. 1A is obtained will be described.

First, the upper surface of a silicon (semiconductor) substrate 1, for which the diameter is eight inches and the plane direction is (100), is cleaned, and a thermal oxide film 2 of about 10 nm thick is formed on the upper surface through thermal oxidization. Further, a silicon nitride (Si₃N₄) film 3, about 100 to 250 nm thick, is formed on the thermal oxide film 2, using a pressure reduction CVD method.

It should be noted that this silicon substrate 1 includes a logic region, composed of a high breakdown voltage transistor region A, a low breakdown voltage transistor region B and a fast transistor region D, and a memory region C.

Following this, as shown in FIG. 1B, the silicon nitride film 3 is patterned using RIE (Reactive Ion Etching), while employing a fluorine gas as an etching gas, to form a first opening 3a in the portion of the silicon nitride film 3 that is used as a device isolation region. Further, during this patterning process, the portion of the silicon nitride film 3 in the memory region C, whereat a cell capacitor is to be formed later, is etched, and a second opening 3b is thus obtained.

Sequentially, the thermal oxide film 2 and the silicon substrate 1 under the first and the second openings 3a and 3b are etched, using a chlorine gas as the etching gas, and a device isolation groove 1a is formed under the first opening 3a, while a capacitor formation groove 1b is formed under the second opening 3b. The depths of these grooves 1a and 1b are not especially limited, and in this embodiment, are 200 to 400 nm, for example. Furthermore, the direction in which the device isolation groove 1a and the capacitor formation groove 1b are extended is not especially limited, and in this embodiment, these grooves 1a and 1b are formed, so that the plane directions of the side surfaces of the grooves 1a and 1b are (110).

Thereafter, in order to recover the damage on the surfaces of the grooves 1a and 1b using etching, the exposed surface of the silicon substrate 1 is thermally oxidized to form a thermal oxide film (not shown), about 10 nm thick, on the surfaces of the grooves 1a and 1b.

The processing performed until the structure in cross section shown in FIG. 1C is obtained will now be described.

First, a silicon oxide (SiO₂) film is formed on the silicon nitride film 3 through the HDPCVD (High Density Plasma CVD) method, using silane as a reaction gas, and the device isolation groove 1a and the capacitor formation groove 1b are completely filled with the silicon oxide film. Then, through the CMP (Chemical Mechanical Polishing) method, the silicon oxide film portion on the silicon nitride film 3 is polished and removed, while that in the grooves 1a and 1b is retained as device isolation insulating film 4. Use of such a device isolation structure is also called STI (Shallow Trench Isolation).

Thereafter, as a process for increasing the density of the device isolation insulating film 4, it is preferable that annealing be performed at a substrate temperature of 1000° C. in a nitrogen atmosphere.

Next, as shown in FIG. 1D, a photoresist is applied across the entire upper surface of the silicon substrate 1, and is exposed and developed, so that a first resist pattern 6, having a window 6a, is formed on the capacitor formation groove 1b.

Then, through plasma etching using a gas mixture of C₄F₃, Ar, CO and O₂, the device isolation insulating film 4 is removed from the capacitor formation groove 1b through the window 6a. At this time, not all the device isolation insulating film 4 need be removed from inside the capacitor formation groove 1b, and part of this film 4 may remain on the bottom of the capacitor formation groove 1b.

Thereafter, the first resist pattern 6 is removed.

Following this, as shown in FIG. 1E, the silicon nitride film 3 and the thermal oxide film 2 are removed using thermal phosphoric acid, and the clean surface of the silicon substrate 1 is exposed. Then, a thermal oxide film about 10 nm thick is again formed on the exposed surface of the silicon substrate 1, and is used as a protective film 7.

By using the protective film 7 as a through film, n impurity ions, such as phosphorus or arsenic is ion-implanted in the silicon substrate 1 to form first to fourth n wells 12 to 15 in the silicon substrate 1. The third n well 14 is arranged at a depth deeper than the capacitor formation groove 1b in the memory region C, and the remaining n wells are arranged in the portions, the transistor regions A, B and D, wherein p MOS transistors are to be formed.

In the same manner, p impurity ions, such as boron ions, are implanted in the silicon substrate 1, and first to third p wells 8 to 10 are formed in the portions, the transistor regions A, B and D, wherein n MOS transistors are to be formed.

Sequentially, channel doping and ion implantation for the adjustment of a threshold voltage are performed for the first to the fourth n wells 12 to 15 and the first to the third p wells 8 to 10, and an annealing process is performed at a substrate temperature of 900 to 1050° C., in a nitrogen atmosphere, to disperse the impurities in the respective wells 8 to 10 and 12 to 15.

It should be noted that separate resist patterns (not shown) are employed to perform the ion implantation of the n impurities and the p impurities, and after the ion implantation has been completed, the resist patterns are removed.

Sequentially, as shown in FIG. 1F, wet etching is performed for the protective film 7, which is employed as a through film for ion implantation, and the clean surface of the silicon substrate 1 is exposed again. During the wet etching process, a hydrogen fluoride (HF) solution, for example, is employed as an etching fluid.

Thereafter, the silicon substrate 1 is cleaned, using a chemical fluid, to remove particles and metal, for example, adhering to the surface of the silicon substrate 1.

Following this, as shown in FIG. 1G, with the condition that the substrate temperature be 750 to 850° C., a thermal oxide film about 5 to 8 nm thick is formed by thermally oxidizing the exposed surface of the silicon substrate 1, and is used as a first insulating film 17.

Further, as shown in FIG. 1H, by employing the first insulating film 17 as a through film, fluorine ions (F) are implanted into the entire upper surface of the silicon substrate 1 in a direction perpendicular to the in-plane direction, so that fluorine is introduced into the upper surface of the silicon substrate 1 and the bottom 1c of the capacitor formation groove 1b. The ion implantation condition is not especially limited, and in this embodiment, it is preferable that the acceleration energy be 1 to 20 KeV and the dose be 10¹⁴ to 10¹⁵ cm³.

As a result of the ion implantation, the introduction of fluorine into the side surfaces, which are nearly vertical, of the capacitor formation groove 1b is suppressed, while a large amount of fluorine is introduced into the upper surface of the semiconductor substrate 1 and the bottom 1c of the capacitor formation groove 1b. As a result, the amount of fluorine implanted in the upper surface of the silicon substrate 1 and the bottom 1c can be greater than the amount implanted in the side surfaces.

Furthermore, since the mass of fluorine is small, the first insulating film 17 is only lightly damaged during the ion implantation process. Therefore, deterioration of the first insulating film 17, which later serves as a gate insulating film in the high breakdown voltage transistor region A, can be disregarded.

Next, as shown in FIG. 1I, a photoresist is applied across the entire upper surface of the silicon substrate 1 and is exposed and developed so that a second resist pattern 20 is obtained that covers the high breakdown voltage transistor region A. The regions other than the high breakdown voltage transistor region A, which are B to D are not covered by the second resist pattern 20, and in those regions, the device isolation insulating film 4 and the first insulating film 17 are exposed.

While using the second resist pattern 20 as an etching mask, the first insulating film 17 is removed from the regions B to D using a hydrogen fluoride (HF) solution, so that the first insulating film 17 is left only in the high breakdown voltage transistor region A.

After the second resist pattern 20 has been removed, the upper surface of the silicon substrate 1 and the inner surface of the capacitor formation groove 1b are cleaned using a chemical fluid, and particles and metal, for example, are removed from the surfaces. The chemical fluid can be either SPM, which is a mixture of sulfuric acid and a hydrogen peroxide solution, APM, which is formed by dissolving ammonia in a hydrogen peroxide solution, or HPM, which is a mixture of hydrochloric acid and a hydrogen peroxide solution.

After the above described cleaning, a residual natural oxide film, called a chemical oxide film, is present on the surface of the silicon substrate 1, and the clean surface of the silicon substrate 1 is covered with the chemical oxide film.

In order to remove this chemical oxide film, the silicon substrate 1 is placed in a rapid heating/cooling apparatus, for example, and with the condition that the substrate temperature be 900 to 1050° C. in the reduced pressure state, a hydrogen annealing process is performed for the silicon substrate 1 in a hydrogen atmosphere. The annealing period is not especially limited; however, sixty seconds or shorter is preferable.

Through the above described hydrogen annealing process, the chemical oxide film on the surface of the silicon substrate 1 is reduced, and the clean surface of the silicon substrate 1 is exposed.

Then, as shown in FIG. 1J, with the condition that the substrate temperature be 750 to 850° C., for example, the entire upper surface of the silicon substrate is again thermally oxidized, and a thermal oxide film about 2 to 5 nm thick is formed on the surface of the silicon substrate 1 in the regions B to D and is used as a second insulating film 18. In the high breakdown voltage transistor region A, through this thermal oxidization, the portion of the silicon substrate 1 under the first insulating film 17 is oxidized, and the thickness of the first insulating film 17 is increased.

Thereafter, to recover the damage to the silicon substrate 1 received during the fluorine ion implantation process, as explained while referring to FIG. 1H, the thermal treatment is performed for the silicon substrate in an N₂ atmosphere, with the condition that the substrate temperature be 900° C. or higher.

Following this, as shown in FIG. 1K, a photoresist is applied to the entire upper surface of the silicon substrate 1 and is exposed and developed. Thus, a third resist pattern 21 is formed to cover the high breakdown voltage transistor region A, the low breakdown voltage transistor B and the memory region C. Since the high-speed transistor region D is not covered with the third resist pattern 21, the second insulating film 18 is exposed in this region.

Then, using the third resist pattern 21 as an etching mask, the second insulating film 18 is etched and removed from the high-speed transistor region D, so that the second insulating film 18 remains only in the low breakdown voltage transistor region B and the memory region C.

Thereafter, the third resist pattern 21 is removed.

Sequentially, as shown in FIG. 1L, with the condition that the substrate temperature be about 750 to 850° C., the entire upper surface of the silicon substrate is thermally oxidized again, and a thermal oxide film about 1 to 2 nm thick is formed on the surface of the silicon substrate 1 in the high-speed transistor region D, and is used as a third insulating film 19. During this thermal oxidization process, since the surface portions of the silicon substrate 1 in the areas A to C are also oxidized, in addition to the high-speed transistor region D, the thicknesses of the previously formed first and second insulating films 17 and 18 are increased.

Through the processes described above, the first to the third insulating films 17 to 19, which are to be patterned later to serve as gate insulating films, are formed in the descending order of thickness in the high breakdown voltage transistor region A, the low resistance voltage transistor region B and the high-speed transistor region D.

The process performed to obtain the structure shown in cross section in FIG. 1M will now be described.

First, using the low pressure CVD method, a polycrystal silicon film (a conductive film) about 200 nm thick is formed on the first to third insulating films 17 to 19. The polycrystal silicon film is used as a gate electrode for an MOS transistor, and impurities may be in-situ doped. In this case, phosphorus is doped, as an n-type impurity, into the polycrystal silicon film in the n-type MOS transistor formation region, while boron is doped, as a p-type impurity, into the polycrystal silicon film in the p-type MOS transistor formation region.

Following this, the polycrystal silicon film is patterned using photolithography so that gate electrodes 23a remain in the respective areas A to D.

At the same time, in the memory region C, the polycrystal silicon film is patterned so that a capacitor upper electrode 23b remains inside the capacitor formation groove 1b and on the surrounding second insulating film 18.

Thereafter, while employing the gate electrodes 23a as masks, phosphorus ions are implanted as n-type impurities in portions of the silicon substrate 1, in the high breakdown voltage transistor region A, the low breakdown voltage region B and the high-speed transistor region D, where n-type MOS transistors are to be formed, and first to third n-type source/drain extensions 24a to 24c are formed in a self-matching manner with the gate electrodes 23a.

Furthermore, p-type impurity ions, such as boron ions, are likewise implanted in portions of the silicon substrate 1, in the areas A to D, where p-type MOS transistors are to be formed, and first to fourth p-type source/drain extensions 24d to 24g are formed in a self-matching manner with the gate electrodes 23a.

It should be noted that in the above ion implantation process, the n-type impurities and the p-type impurities are separately implanted by using a resist pattern (not shown).

The process performed to obtain the structure shown in cross section in FIG. 1N will now be explained.

First, using the CVD method, a silicon oxide film about 100 to 150 nm thick is formed across the entire upper surface of the silicon substrate 1, and is thereafter etched back so that it remains as insulating side walls 26 on the side faces of the gate electrodes 23a and of the capacitor upper electrode 23b.

During the etching back process, the first to the third insulating films 17 to 19 are also etched back so that only those portions beneath the insulating side walls 26 and the gate electrodes 23a remain. In the areas A to D, the portions of the first to third insulating films 17 to 19 that are beneath the gate electrodes 23a and are not etched, serve as first to third gate insulating films 17a to 19a, the thicknesses of which are reduced in the named order. Because of the differences in the thicknesses, the breakdown voltage of the first gate insulating film 17a is the highest, and the breakdown voltage is reduced, in order, for the second gate insulating film 18a and the third gate insulating film 19a.

Further, the remainder of the second insulating film 18, which surrounds and lies beneath the capacitor upper electrode 23b, extending down into and across the bottom of the capacitor formation groove 1b, is used as a capacitor dielectric film 18b.

Next, n-type impurity ions, such as phosphorus ions or arsenic ions, are implanted in the silicon substrate 1 by employing the insulating side walls 26 as masks. Thus, in the high breakdown voltage transistor region A, the low resistance voltage transistor region B and the high-speed transistor region D, first to third n-type source/drain areas 27a to 27c are formed in the portions of the silicon substrate 1 where n-type MOS transistors are to be formed.

Similarly, p-type impurity ions, such as boron ions, are implanted in the portions of the silicon substrate 1 in the areas A to D where p-type MOS transistors are to be formed, so that in these portions, first to fourth p-type source/drain areas 27d to 27g are formed.

Following this, a cobalt layer is formed using the sputtering method. Thereafter, the silicon substrate 1 is heated to cause a reaction between the cobalt and silicon, and a cobalt silicide layer 28 is formed on the surface layer portions of the source/drain areas 27a to 27g. The cobalt silicide layer 28 is also formed on the gate electrodes 23a and the capacitor upper electrode 23b, so that the gate electrodes 23a become a polycide structure.

Thereafter, the non-reacting portions of the cobalt silicide layer 28 on the device isolation insulating film 4, for example, are removed by wet etching.

Through the above described processing, an n-type high breakdown voltage MOS transistor TR (high)ₙ and a p-type high breakdown voltage MOS transistor TR (high)ₚ are formed in the high breakdown voltage transistor region A; an n-type low breakdown voltage MOS transistor TR (low)ₙ and a p-type low breakdown voltage MOS transistor TR (low)ₚ are formed in the low breakdown voltage transistor region B; two cell transistors TR_{cell}, which are p-type MOS transistors, are formed in the memory region C; and an n-type high-speed MOS transistor TRₙ and a p-type high-speed MOS transistor TRₚ are formed in the high-speed transistor region D.

On the other hand, in the memory region C, the basic structure is completed of a cell capacitor Q that includes the capacitor upper electrode 23b and the capacitor dielectric film 18b and for which the silicon substrate 1 serves as the lower electrode.

Before the cobalt silicide layer 28 is formed, a channel impurity may be obliquely introduced over the gate electrodes 23a to form pocket areas in the source/drain areas 27a to 27g. When such pocket areas are formed, the threshold voltages for the above described respective transistors can be prevented from being too low, and the roll-off resistance can be increased.

The process performed to obtain the structure shown in cross section in FIG. 10 will now be described.

First, using the low pressure CVD method, a silicon nitride film about 5 to 100 nm thick is formed as a cover insulating film 30 across the entire upper surface of the silicon substrate 1, and using the HDPCVD method, a silicon oxide film about 500 to 1500 nm thick is formed as a fourth insulating film 31 on the cover insulating film 30. The upper surface of the fourth insulating film 31 is polished and planarized using the CMP method, and the cover insulating film 30 and the fourth insulating film 31 are employed as an inter-layer insulating film 32.

Sequentially, the inter-layer insulating film 32 is patterned using photolithography, and holes are formed above the respective source/drain areas 27a to 27d of the MOS transistors, and above the upper electrode 23b of the cell capacitor Q. Then, using the sputtering method, a silicon nitride film is formed as a glue film on the inner surfaces of the holes and on the upper surface of the inter-layer insulating film 32. Thereafter, a tungsten film is formed on the glue film using the CVD method and employing tungsten hexafluoride as a reaction gas to completely fill the holes.

Thereafter, extra portions of the glue film and the tungsten film on the inter-layer insulating film 32 are polished and removed using the CMP method, so that only the film in the holes remains. The remaining glue film and tungsten film serve as first conductive plugs 35 in the holes located above the respective source/drain areas 27a and 27d, and also as a second conductive plug 36 in the hole located above the upper electrode 23b of the cell capacitor Q.

Then, a metal film lamination, consisting mainly of aluminum film, is formed on the inter-layer insulating film 32, and is patterned to obtain metal wiring 34.

Through the above described processing, the basic structure of a semiconductor device according to this embodiment is completed.

In this semiconductor device, two cell transistors TR_{cell} in the memory region C are employed to write information to the cell capacitor Q. The transistors formed in the high breakdown voltage transistor region A, the low breakdown voltage transistor region B and the high-speed transistor region D constitute a logic circuit, and are used, for example, for writing and reading the cell capacitor Q.

According to the above described semiconductor device manufacturing method, as shown in FIG. 1H, fluorine ions are implanted into the capacitor formation groove 1b, the plane direction of which differs for the side surfaces and the bottom surface, and as shown in FIG. 1J, the inner surface of the capacitor formation groove 1b is thermally oxidized to obtain the second insulating film 18 that later serves as a capacitor dielectric film.

The present inventor has conducted the following experiment in order to examine the effects that implantation of such fluorine ions provides for the second insulating film 18.

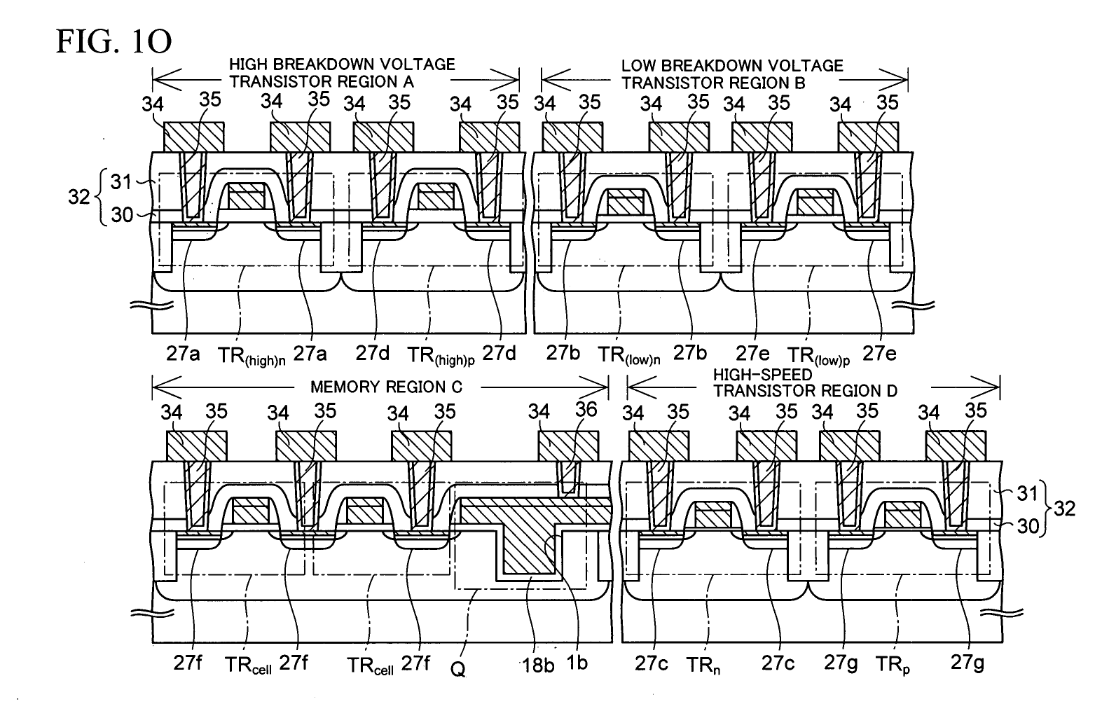

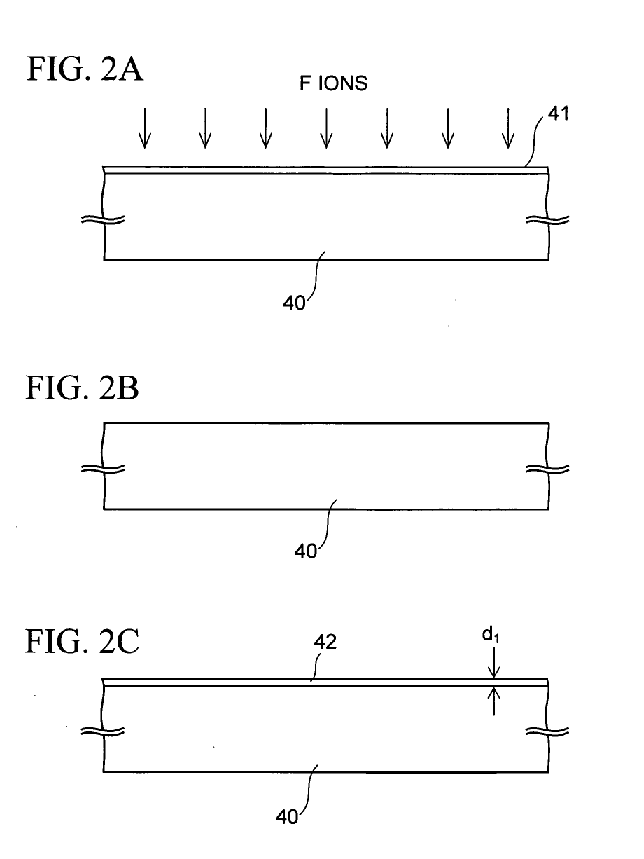

FIGS. 2A to 2C are cross-sectional views for explaining the experiment.

In this experiment, as shown in FIG. 2A, the surface of a silicon substrate 40 having the plane direction (100) was thermally oxidized, and a first thermal oxide film 41 about 6 nm thick was formed on the surface.

By using the first thermal oxide film 41 as a through film, fluorine ions were implanted in the silicon substrate 40 in a direction perpendicular to the in-plane direction.

Following this, as shown in FIG. 2B, using a hydrogen fluoride solution, the first thermal oxide film 41 was removed by wet etching to expose the clean surface of the silicon substrate 40.

Thereafter, as shown in FIG. 2C, with the condition that the substrate temperature be 750° C. and the oxidization period be 180 seconds, the surface of the silicon substrate 40 was again thermally oxidized, and a second thermal oxide film 42 was formed on the upper surface of the silicon substrate 40. It should be noted that the oxidization condition described above is a condition for which the thickness of the thermal oxide film on the silicon substrate 40 is 2.5 nm when fluorine ions are not implanted.

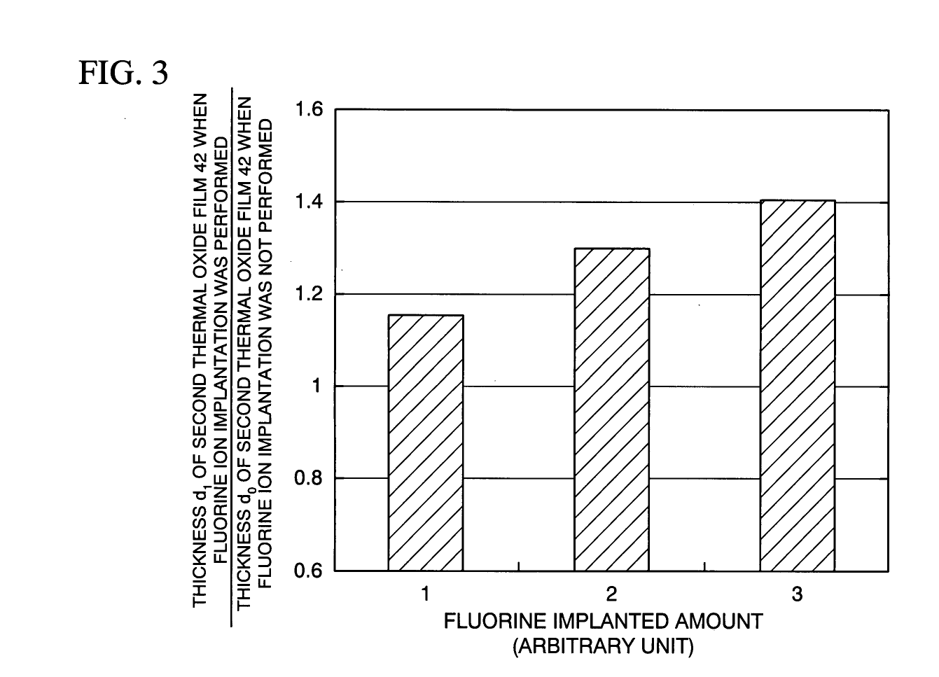

FIG. 3 is a graph obtained by calculating a ratio d₁/d₀ for a thickness d₁ of the second thermal oxide film 42, obtained when fluorine ions were implanted as shown in FIG. 2A, to a thickness d₀, obtained when fluorine ions were not implanted. It should be noted that in this examination the amount (the dose) of fluorine implanted varied, and that the ratio d₁/d₀ was obtained for each implanted amount.

As understood from FIG. 3, the ratio d₁/d₀ is greater than 1 when fluorine ion implantation is performed. From this, it is apparent that the effect produced by fluorine provides for an increase in the speed of oxidization on the plane (100) of the silicon substrate 1, and that the speed-increasing effect becomes greater as the amount implanted is increased. In particular, it is apparent, especially when the amount (the dose) of fluorine ions implanted is an arbitrary unit of 3, a second thermal oxide film 42 can be obtained that is 1.4 times as thick as when fluorine ions are not implanted.

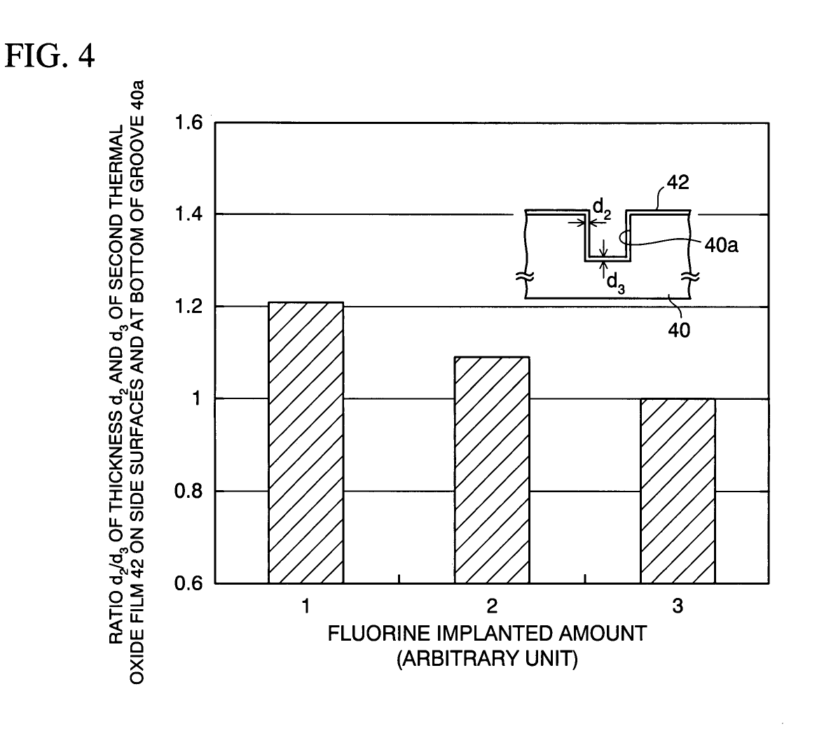

FIG. 4 is a graph obtained, on the assumption that a groove 40a having a plane direction (100) at the bottom is formed in the silicon substrate 40 having the plane direction of (100), by calculating, using the results shown in FIG. 3, a ratio d₂/d₃ of thicknesses d₂ and d₃ for the second thermal oxide film 42 on the side surfaces and at the bottom of the groove 40a. It should be noted that the plane direction of the side surfaces of the groove 40a is (110) and fluorine ion implantation is not performed for the side surfaces. Furthermore, for this graph, based on the teaching of the Patent Literature 1, the thickness d₂ of the second thermal oxide film 42 on the side walls of the groove 40a is set as 1.4 times the thickness at the bottom when fluorine ions are not implanted. Then, as in FIG. 3, the amount of implanted fluorine using an arbitrary unit is adopted as the horizontal axis of the graph.

As apparent from FIG. 4, when the amount of implanted fluorine is one of arbitrary units 1 to 3, the thickness d₂ of the second insulating film 42 on the side surfaces of the groove 40a is less than 1.3 times the thickness d₃ at the bottom, so that the ratio of the thicknesses d₂ to d₃ can be smaller than the conventional ratio. Further, when the amount of implanted fluorine is increased, the film thickness ratio d₂/d₃ can be small, or when the amount of implanted fluorine is an arbitrary unit of 3, the film thickness ratio d₂/d₃ can be 1.

It should be noted that, in the examination for FIG. 4, the film thickness ratio d₂/d₃ for the thermal oxide film 42 on the side surfaces and at the bottom of the groove 40a was calculated; however, the film thickness ratio result obtained for the thermal oxide film 42 on the side surfaces of the groove 40a and on the upper surface of the silicon substrate 40 was the same.

In the fluorine ion implantation process described while referring to FIG. 1H, since fluorine ions are introduced in a direction perpendicular to the in-plane direction of the silicon substrate 1, fluorine is introduced into the bottom of the capacitor formation groove 1b, while there is no substantial implantation in the side surfaces. Therefore, the amount of fluorine implanted is increased at the bottom of the capacitor formation groove 1b, and is reduced at the side surfaces, so that for the second insulating film 18, formed during the process in FIG. 1J, there is a small difference in the thicknesses on the side surfaces and at the bottom of the capacitor formation groove 1b. For the same reason, the difference in the thicknesses of the second insulating film 18 on the upper surface of the silicon substrate 1 and on the side surfaces of the capacitor formation groove 1b is reduced. As a result, the second insulating film 18 can be arranged so it is equally thin on the side surfaces and at the bottom of the capacitor formation groove 1b, and the capacitance of the cell capacitor Q (see FIG. 1N), which employs the second insulating film 18 as a capacitor dielectric film, can be increased.

In addition, for the same reason as described above, the difference in the thicknesses of the second insulating film 18 on the upper surface of the silicon substrate 1 and on the side surfaces of the capacitor formation groove 1b is also reduced, as well as in FIG. 4.

On the other hand, in an oxidization atmosphere containing a fluorine compound described in the Patent Literature 3, fluorine is equally introduced into the side surfaces and the bottom of the capacitor formation groove 1b, and it is considered difficult for fluorine to be selectively introduced into the bottom. Therefore, it is difficult for differences in the thickness of the second insulating film 18 to be reduced as in this embodiment.

Furthermore, in the conventional example for which fluorine ion implantation is not performed and the second insulating film 18 grows thick on the side surfaces of the capacitor formation groove 1b, the portion of the second insulating film 18 on the upper surface of the silicon substrate 1 must be thinner than necessary in order to reduce the thickness of the second insulating film 18 on the side surfaces of the capacitor formation groove 1b. However, with the conventional method, since the second gate insulating film 18a formed on the upper surface of the silicon substrate 1 becomes thinner than necessary, a current leak through the second gate insulating film 18a is increased, and the reliability of the low breakdown voltage MOS transistors TR(low)ₙ and TR(low)ₚ and the cell transistor TR_{cell}, which utilize the second gate insulating film 18a, is reduced.

On the other hand, in this embodiment, as previously described, a second insulating film 18 having almost the same thickness is formed on the side surfaces and at the bottom of the capacitor formation groove 1b. Therefore, the thickness of the second insulating film 18 on the upper surface of the silicon substrate 1 need not be reduced more than necessary, and the reliability of the respective MOS transistors TR(low)ₙ, TR(low)ₚ and TR_{cell}, which employ the second insulating film 18 as a gate insulating film, can be improved.

As described above, according to this embodiment, both the capacitance of the cell capacitor Q and the reliability of the MOS transistors TR(low)ₙ, TR(low)ₚ and TR_{cell} can be increased, and a high-quality semiconductor device can be provided.

Further, since unlike a group III element, such as boron, or a group V element, such as phosphorus or arsenic, fluorine ions to be implanted rarely become a source of supply for carriers, when fluorine ions are implanted, it is difficult for the electric characteristics of the MOS transistors TR(high)ₙ, TR(high)ₚ, TR(low)ₙ, TR(low)ₚ, TR_{cell} TRₙ and TRₚ to be deteriorated. Therefore, this embodiment can be especially appropriate for a semiconductor device wherein transistors and a cell capacitor are mounted together.

It should be noted that in this embodiment the plane directions of the silicon substrate 1 and the side surfaces of the capacitor formation groove 1b are not especially limited.

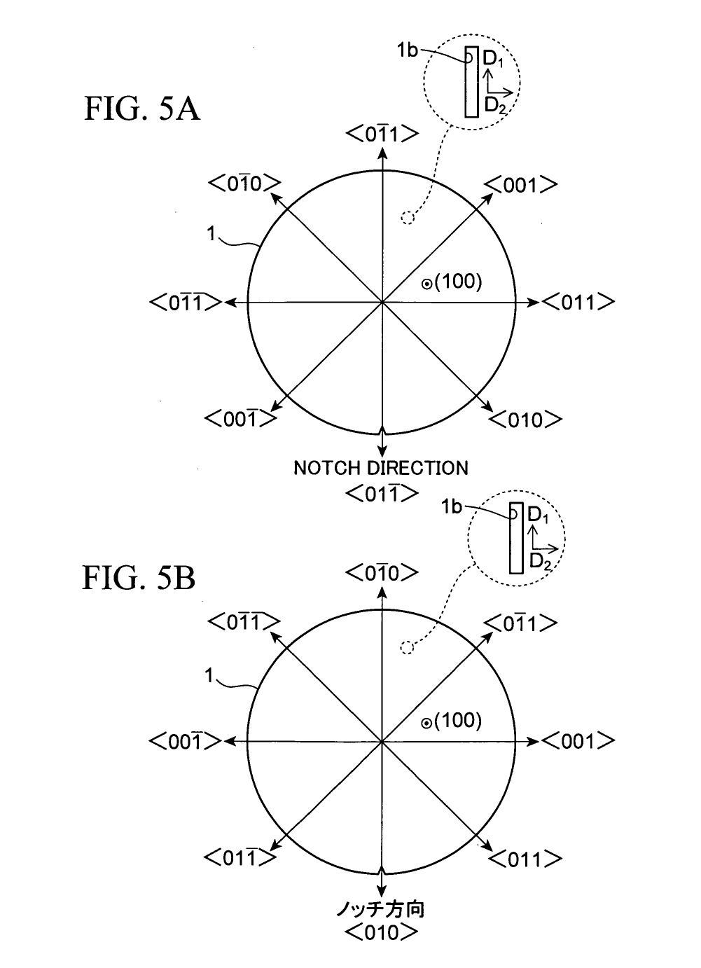

FIGS. 5A and 5B are plan views for explaining the plane direction of a silicon substrate 1 that can be employed for this embodiment.

FIG. 5A is a plan view of a silicon substrate 1 normally employed in the semiconductor device manufacturing process, and in this embodiment, such a silicon substrate 1 is employed. In this example, the plane direction of the silicon substrate 1 is (100), and the notch direction is <011-> (symbol “−” is a bar provided on the preceding character). In this case, when a direction D₂ perpendicular to an extended direction D₁ of the capacitor formation groove 1b is set to as one of <011>, <01-1->, <011->and <01-1>, the plane direction of the side surfaces of the capacitor formation groove 1b become (110) surface.

FIG. 5B is a plan view of the silicon substrate 1b obtained when the notch direction is rotated 45° clockwise from FIG. 5A. In this case, when the direction D₂ is set to as one of <001>, <001->, <010> and <01-0

>, the plane direction of the side surfaces of the capacitor formation groove 1b become (100) plane, which is equivalent to the plane direction of the silicon substrate 1.

For the semiconductor device according to the first embodiment, or to a second or a third embodiment that will be described later, by using either one of the silicon substrates 1 in FIGS. 5A and 5B, the difference in the thicknesses of the second insulating film 18 on the side surfaces and at the bottom of the capacitor formation groove 1b can be reduced.

Furthermore, the differences in the thickness of the second insulating film 18 occurs because the plane direction is different for the side surfaces and the bottom of the capacitor formation groove 1b. However, it is recognized that differences in the film thickness also occur as a result of other factors. For example, when the capacitor formation groove 1b is formed using RIE, explained while referring to FIG. 1B, it is recognized that differences in the thickness of the second insulating film 18 also depend on the condition of the etching performed using RIE.

In this embodiment, regardless of the cause of the differences in the film thickness, a film thickness ratio of less than 1.3 times, which can not be obtained conventionally, can be realized.

Further, in this embodiment, the gate insulating film 18a for the cell transistor TR_{cell} and the capacitor dielectric film 18b for the cell capacitor Q have been formed using the second insulating film 18, which serves as the gate insulating film 18a for the low breakdown voltage MOS transistors TR(low)ₙ and TR(low)ₚ. However, the present invention is not limited to this. For example, the first insulating film 17 or the third insulating film 19 may be employed to form the gate insulating film 18a for the cell transistor TR_{cell} and the capacitor dielectric film 18b for the cell capacitor Q. This also applies for the following embodiments.

In addition, in this embodiment, the high breakdown voltage MOS transistors TR(high)ₙ and TR(high)ₚ, the low breakdown voltage MOS transistors TR(low)ₙ and TR(low)ₚ and the cell transistor TR_{cell} are employed together on the semiconductor substrate 1. However, another combination of transistors may be employed.

### (2) Second Embodiment

In the first embodiment, before the second insulating film 18 is formed, fluorine ion implantation is performed for the silicon substrate 1.

In the second embodiment, instead of performing such fluorine ion implantation, an improved method of forming a second insulating film 18 is employed to reduce the difference in the thicknesses of the second insulating film 18 on the side surfaces and at the bottom of a capacitor formation groove 1b.

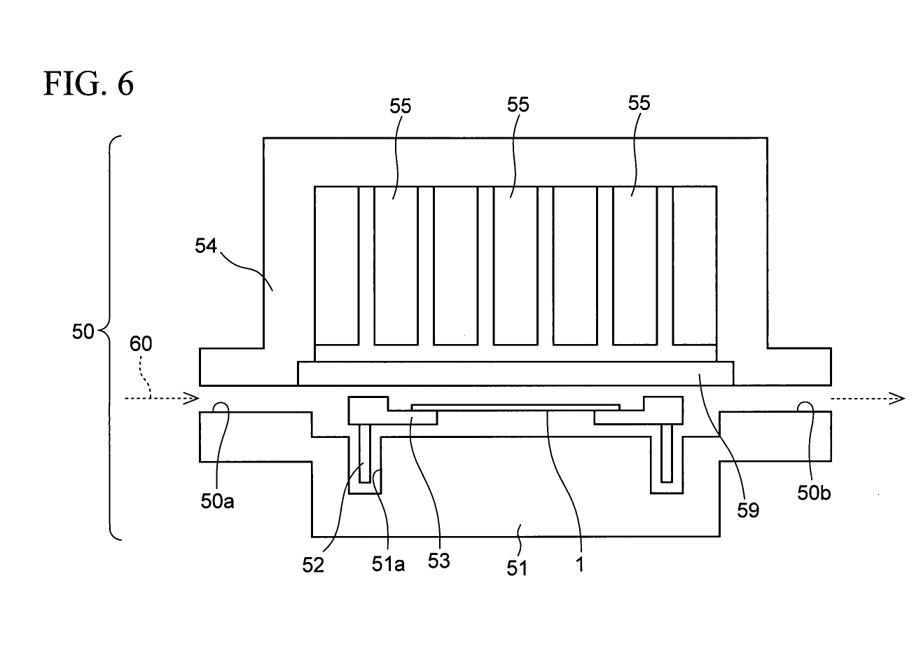

FIG. 6 is a diagram showing the structure of a process chamber used for this embodiment.

A process chamber 50 includes a base 51, and a cylinder 52 that is fitted into a hole 51a in the base 51 and can descend and ascend. A ring plate 53, for supporting a silicon substrate 1, is attached to the upper end of the cylinder 52, and an upper cover 54 is provided above the ring plate 53. A plurality of lamps 55, for heating the silicon substrate 1, are stored in the upper cover 54, and a transparent quartz window 59, through which passes light from the lamps 55, is arranged at the lower end of the upper cover 54. The process chamber 50 also includes a gas inlet port 50a, for internally introducing a treating gas 60, and a gas outlet port 50b, for externally discharging the treating gas 60 when it is no longer required. Using a vacuum pump (not shown) connected to the gas outlet port 50b, the internal process chamber 50 pressure can be reduced to lower than the external atmospheric pressure.

In this process chamber 50, the silicon substrate 1, which is held at a predetermined height by the cylinder 52, is heated by the radiant heat emitted by the lamps 55, and is also exposed to the treating gas 60, which is introduced through the gas inlet port 50a.

In this embodiment, using this process chamber 50, a semiconductor device is manufactured in the following manner.

First, the processes in FIGS. 1A to 1G explained in the first embodiment are performed, and as shown in FIG. 1G, a first insulating film 17 is formed on the surface of the silicon substrate 1 in the areas A to D.

Then, instead of performing the fluorine ion implantation in FIG. 1H, as explained while referring to FIG. 1I, etching is performed to remove the first insulating film 17 from all areas other than the high breakdown voltage transistor region A. Then, a second resist pattern 20, used as an etching mask, is removed.

Subsequently, in order to remove, for example, particles and metal adhering to the surface of the silicon substrate 1, the upper surface of the silicon substrate 1 and the inner surface of the capacitor formation groove 1b are cleaned using a chemical fluid, such as SPM, APM or HPM.

Following this, the silicon substrate 1 is placed in the process chamber 50, explained while referring to FIG. 6, in order to remove a chemical oxide film that has formed on the surface of the silicon substrate 1 during the chemical cleaning. Then, the silicon substrate 1 is heated by the lamps 55 to about 900 to 1050° C. Thereafter, as the treating gas 60, a reduced hydrogen gas is introduced into the process chamber 50, which is in a reduced pressure state, and the hydrogen annealing process is initiated for the silicon substrate 1. When the hydrogen annealing process is performed for 60 seconds or less, for example, the chemical oxide film is reduced and removed, and the clean surface of the silicon substrate 1 is exposed.

Next, while the silicon substrate 1 remains in the process chamber 50, the substrate temperature is stabilized at about 800 to 1100° C. by the radiant heat emitted by the lamps 55, and the internal pressure in the process chamber 50 is reduced to about 20 Torr.

Thereafter, a gas mixture of oxygen and hydrogen, for which the flow rate is 10:1 or less, is introduced, as the process gas 60, into the process chamber 50. As the oxygen and hydrogen enter the process chamber 50, they react with each other on the silicon substrate 1 and become vapor, so that the silicon substrate 1 is exposed to the water vapor, and thus a thermal oxide film grows on the surface of the silicon substrate 1. This method of growing the thermal oxide film is also called the inside heating ISSG (In Situ Stream Generation) oxidization method.

When the thickness of the thermal oxide film has reached about 2.5 nm, the supply of hydrogen and oxygen is halted. The thus obtained thermal oxide film is regarded as a second insulating film 18 (see FIG. 1J).

Thereafter, the processes in FIGS. 1K to 1O, explained in the first embodiment, are performed, and as shown in FIG. 10, a cell capacitor Q and a cell transistor TR_{cell} are formed in a memory region C, while MOS transistors TR(high)ₙ, TR(high)ₚ, TR(low)ₙ, TR(low)ₚ, TRₙ and TRₚ are formed in areas other than the memory region C.

In this embodiment, the second insulating film 18, which serves as a capacitor dielectric film for the cell capacitor Q, has been formed using the ISSG oxidization method, in which the surface of the silicon substrate 1 is exposed to the water vapor atmosphere with a reduced pressure state. The present inventor examined the plane direction dependency of an oxide film that was formed using the ISSG oxidization method.

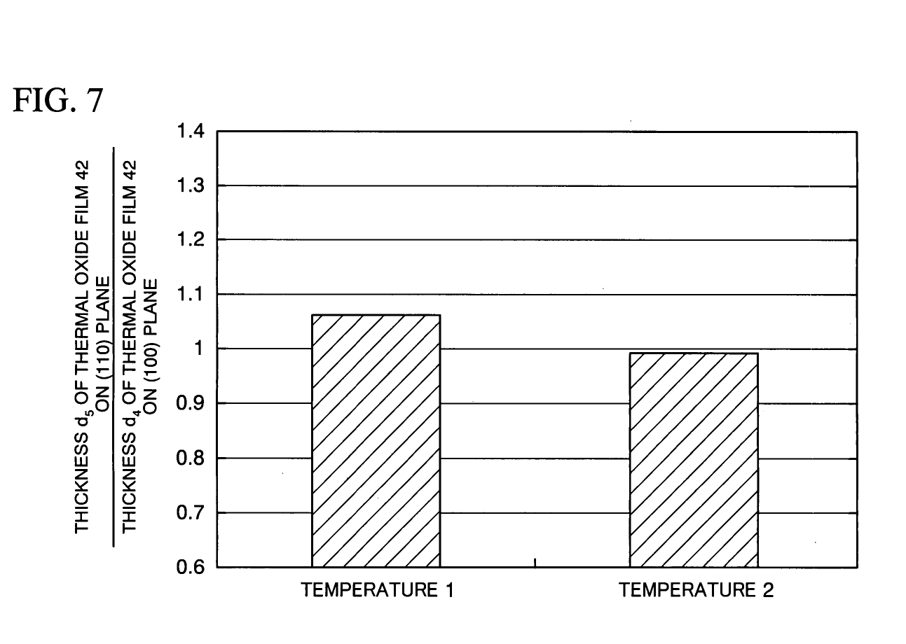

During this examination, two silicon substrates, for which the plane directions of the surfaces were (100) and (110), were cleaned, and using the ISSG oxidization method, a thermal oxide film of about 2.5 nm was formed on the surfaces of these silicon substrates in a water vapor atmosphere of a reduced pressure state, while the substrate temperature was 800 to 900° C. Then, a thickness d₄ of the thermal oxide film on the silicon substrate having the plane direction (100) and a thickness d₅ of the thermal oxide film on the silicon substrate having the plane direction (110) were measured, and a ratio d₅/d₄ was calculated. The obtained result is shown in FIG. 7. It should be noted that this examination was performed at two substrate temperatures, temperature 1 (about 800° C.) and temperature 2 (about 900° C.).

As shown in FIG. 7, in both cases, for the temperatures 1 and 2, the ratio d₅/d₄ was smaller than the 1.3 to 2.0 obtained in the conventional case. Further, when the ratios d₅/d₄ were compared for temperature 1 and temperature 2, it was apparent that the ratio d₅/d₄ for temperature 2, which was higher than temperature 1, was nearer 1.

Based on these results, in this embodiment, the difference in the thicknesses of the second insulating film 18 at the bottom of the capacitor formation groove 1b (see FIG. 1J), for which the plane direction was (100), and on the side surfaces of the capacitor formation groove 1b, for which the plane direction was (110), was smaller than the difference in the conventional case. Similarly, the difference in the thicknesses of the second insulating film 18 on the upper surface of the silicon substrate 1, for which the plane direction was (100), and on the side surfaces of the capacitor formation groove 1b was also reduced.

Therefore, the second insulating film 18 can be formed on the side surfaces of the capacitor formation grove 1b so it is almost as thin as it is at the bottom of the capacitor formation groove 1b and on the upper surface of the silicon substrate 1, and the capacitance of the cell capacitor Q (see FIG. 1N) can be increased.

Further, since there is little difference in the thicknesses of the second insulating film 18 on the side surfaces and at the bottom of the capacitor formation groove 1b, the thickness of the second insulating film 18 on the upper surface of the silicon substrate 1 need not be reduced more than is necessary to obtain a thin second insulating film 18 on the side surfaces of the capacitor formation groove 1b. Therefore, as described above, the capacitance of the cell capacitor Q can be increased, while preventing the current leak of the second gate insulating film 18a from being increased due to such a thin film thickness, the second gate insulating film being formed of the second insulating film 18.

Further, in this embodiment, in the process chamber 50 in FIG. 6, the hydrogen annealing process is performed to remove a chemical oxide film from the surface of the silicon substrate 1, and sequentially, the second insulating film 18 is formed without the silicon substrate 1 being removed from the process chamber 50.

According to this method, since after the hydrogen annealing process has been performed the silicon substrate 1 is not exposed to the atmosphere, the re-forming of a natural oxide film is prevented on the silicon substrate 1 from which the chemical oxide film has been removed, and a second insulating film 18 of high quality can be grown on the clean surface of the silicon substrate 1. Therefore, the reliability of the MOS transistors TR(low)ₙ, TR(low)ₚ, TR_{cell} and the cell capacitor Q, all of which employ the second insulating film 18 as a gate insulating film or a capacitor dielectric film, can be even more increased.

### (3) Third Embodiment

In the first and second embodiment described above, a thermal oxide film (a second insulating film 18), the differences in the thickness of which have been reduced, is formed on the side surfaces and at the bottom of the capacitor formation groove 1b.

In the third embodiment, such a thermal oxide film is formed on the inner surfaces of a device isolation groove 1a.

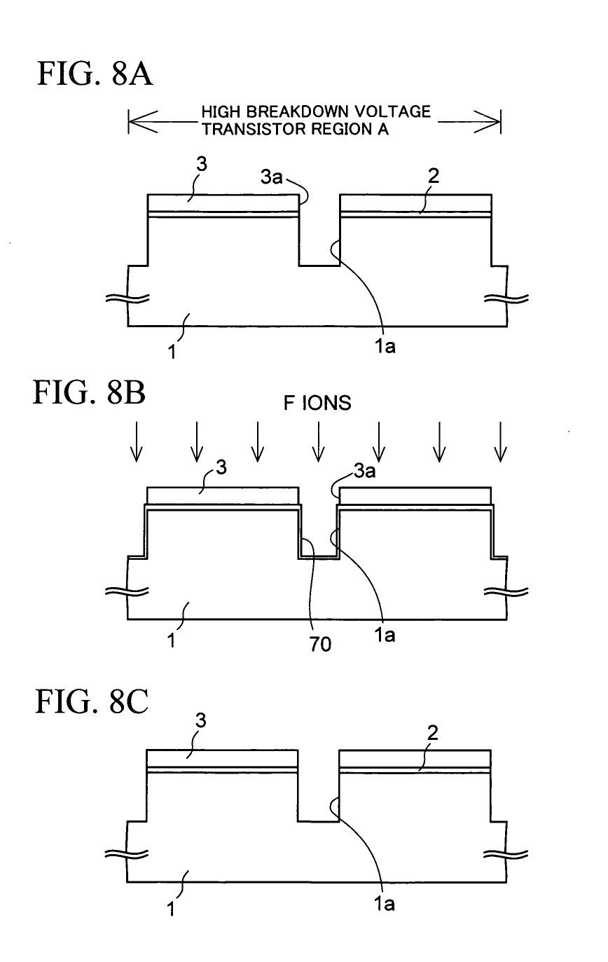

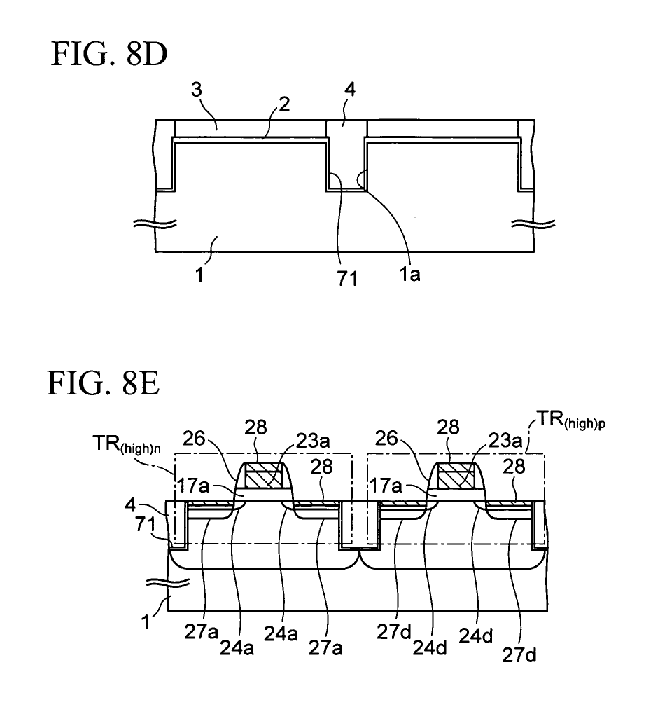

FIGS. 8A to 8E are cross-sectional views of the processing for the manufacture of a semiconductor device according to the third embodiment. In FIGS. 8A to 8E, the same reference numerals as are used in the first and second embodiment are again employed to denote corresponding components, and no further explanation for them will be given. Furthermore, only a high breakdown voltage region A, as explained in the first embodiment, is shown in FIGS. 8A to 8E, no other areas are shown.

First, the processes shown in FIGS. 1A and 1B and explained in the first embodiment are performed, and as shown in FIG. 8A, the device isolation groove 1a is formed in a silicon substrate 1 by etching, using a silicon nitride film 3 as a mask. As in the first and the second embodiments, the plane direction of the surface of the silicon substrate 1 is (100) and the plane direction of the side surfaces of the device isolation groove 1b is (110).

Sequentially, as shown in FIG. 8B, a third thermal oxide film 70 is formed by oxidizing the inner surface of the device isolation groove 1a, and damage caused to the device isolation groove 1a by the etching is recovered. Then, using the third thermal oxide film 70 as a through film, fluorine ions are implanted in the device isolation groove 1a in a direction perpendicular to the in-plane direction of the silicon substrate 1, so that fluorine is introduced into the bottom of the device isolation groove 1a.

Thereafter, as shown in FIG. 8C, the third thermal oxide film 70 is removed by wet etching using a hydrogen fluoride solution.

The process to obtain the structure shown in cross section in FIG. 8D will now be described.

First, with the condition that the substrate temperature is 800 to 900° C., the inner surface of the device isolation groove 1a is thermally oxidized to form a thermal oxide film about 10 nm thick. The obtained film is used as a fifth insulating film 71.

Next, using the HDPCVD method that employs silane as a reaction gas, a silicon oxide film is formed on the fifth insulating film 71 and the silicon nitride film 3, and the device isolation groove 1a is filled completely with the silicon oxide film. Thereafter, extra portions of the silicon oxide film on the silicon nitride film 3 are polished and removed by the CMP method, while the remainder of the silicon oxide film is retained in the device isolation groove 1a as a device isolation insulating film 4. In this manner, the STI device isolation structure is obtained.

Thereafter, the processes performed in FIGS. 1D to 1N and explained in the first embodiment are performed, and as shown in FIG. 8E, the basic structure, including an n-type high breakdown voltage MOS transistor TR(high)ₙ and a p-type high breakdown voltage MOS transistor TR(high)ₚ, is completed.

According to the above described embodiment, since in the process performed in FIG. 8B fluorine ions are implanted in the bottom of the device isolation groove la, as explained in the first embodiment, the speed of oxidization of the thermal oxide film at the bottom is increased. Therefore, the fifth insulating film 71 to be formed after the ion implantation can grow at the same speed on the bottom of the device isolation groove 1a as on the side surfaces, and the difference in the thicknesses of the fifth insulating film 71 on the side surfaces and at the bottom of the groove 1a can be reduced.

In this embodiment, fluorine ion implantation, as explained in the first embodiment, has been performed. However, instead of this, in order to reduce the difference in the thicknesses of the fifth insulating film 71 on the side surfaces and at the bottom of the groove 1a, the inside heating ISSG oxidization method explained in the second embodiment may be employed to form the fifth insulating film 71.

According to the invention, an insulating film is formed by thermally oxidizing the upper surface of a semiconductor substrate and the inner surfaces of a groove, either after fluorine ions have been implanted in the upper surface of the semiconductor substrate and the bottom of the groove, or in a water vapor atmosphere of a reduced internal pressure state. Using this method, a difference in the thicknesses of the insulating film on the side surfaces of the groove and at the bottom, and a difference in the thicknesses of the insulating film on the upper surface of the semiconductor substrate and on the side surfaces of the groove can be reduced. Thus, a thin insulating film can be formed on the side surfaces of the groove as well as on the bottom, and when this insulating film is employed as a capacitor dielectric film for a capacitor, the capacitance of the capacitor can be increased.

What is claimed is:

1. A semiconductor device comprising:
a semiconductor substrate in which a groove is formed; and
an insulating film obtained by thermally oxidizing an upper surface of the semiconductor substrate and a side surface and a bottom surface of the groove,
wherein the thickness of the insulating film formed on the side surface of the groove is less than 1.3 times the respective thicknesses of the insulating film formed on the upper surface of the semiconductor substrate and the bottom surface of the groove.

2. The semiconductor device according to claim 1, wherein a larger amount of fluorine than that implanted in the side surface of the groove is introduced into the upper surface of the semiconductor substrate and into the bottom surface of the groove.

3. The semiconductor device according to claim 1, wherein a capacitor upper electrode is formed on the insulating film, and the capacitor upper electrode, the insulating film and the semiconductor substrate constitutes a capacitor.

4. The semiconductor device according to claim 1, wherein the groove is a device isolation groove, and a device isolation insulating film thick enough to fill the groove is formed on the insulating film.

5. The semiconductor device according to claim 1, wherein a direction perpendicular to a extending direction is one of <001>, <001->, <010> and <01-0> (where symbol “−” denotes a bar provided on a preceding character); and wherein a plane direction of a surface of the semiconductor substrate is (100).

6. The semiconductor device according to claim 5, wherein the semiconductor substrate is a silicon substrate.

7. A semiconductor device manufacturing method comprising the steps of:
forming a groove in a semiconductor device; and
forming an insulating film by at least thermally oxidizing an upper surface of the semiconductor substrate and a bottom surface and side surfaces of the groove,
wherein a step of ion-implanting fluorine ions into the upper surface of the semiconductor substrate and the bottom surface of the groove is performed before the step of forming the insulating film, or the step of forming the insulating film is performed by thermally oxidizing the upper surface of the semiconductor substrate and the bottom surface and the side surface of the groove in a water vapor atmosphere of a reduced pressure state.

8. The semiconductor device manufacturing method according to claim 7, wherein the step of ion-implanting fluorine ions is performed by implanting fluorine into the upper surface of the semiconductor substrate and into the bottom surface of the groove in a direction perpendicular to an in-plane direction of the semiconductor substrate.

9. The semiconductor device manufacturing method according to claim 7, wherein the step of thermally oxidizing the upper surface of the semiconductor substrate and the groove in the water vapor atmosphere is performed by supplying hydrogen and oxygen to a chamber, and by causing a reaction between the hydrogen and the oxygen on the semiconductor substrate which is heated in the chamber.

10. The semiconductor device manufacturing method according to claim 9, further comprising the step of:
before the step of thermally oxidizing the upper surface of the semiconductor substrate and the groove in the water vapor atmosphere, introducing a reducing gas into the chamber and exposing the upper surface of the semiconductor substrate and the groove to the reducing gas,
wherein, without removing the semiconductor substrate from the chamber, the upper surface of the semiconductor substrate and the groove are consecutively exposed to the water vapor atmosphere, and the insulating film is formed on the upper surface and the groove.

11. The semiconductor device manufacturing method according to claim 10, wherein hydrogen is employed as the reducing gas.

12. The semiconductor device manufacturing method according to claim 10, further comprising the step of:
before exposing the groove to the reducing gas, cleaning the upper surface of the semiconductor substrate and the inner surface of the groove with a chemical fluid.

13. The semiconductor device manufacturing method according to claim 7, further comprising the step of:
forming a capacitor upper electrode on the insulating film, so that a capacitor is constructed from the capacitor upper electrode, the insulating film and the semiconductor substrate.

14. The semiconductor device manufacturing method according to claim. 13, further comprising the steps of:
forming a conductive film on the insulating film;
patterning the conductive film to make the conductive film above the grove into the capacitor upper electrode, and
to make the conductive film in a first region of the semiconductor substrate into a gate electrode; and
patterning the insulating film to make the insulating film under the capacitor upper electrode into a capacitor dielectric film, and to make the insulating film under the gate electrode into a gate insulating film.

15. The semiconductor device manufacturing method according to claim 14, further comprising the steps of:
thermally oxidizing the upper surface of the semiconductor substrate in a second region to form an another insulating film having a thickness differing from that of the insulating film; and
patterning the another insulating film to form another gate insulating film having a breakdown voltage differing from that of the gate insulating film.

16. The semiconductor device manufacturing method according to claim 7, wherein a device isolation groove is formed as the groove, and further comprising the step of:
forming a device isolation insulating film on the insulating film to a thickness that is sufficient for filling the groove.

17. The semiconductor device manufacturing method according to claim 7, wherein a silicon substrate is employed as the semiconductor substrate.
